(19) United States
(12) Patent Application Publication
(10) Pub. No.: US 2018/0047791 A1
(43) Pub. Date: Feb. 15, 2018

(54) DISPLAY DEVICE

(71) Applicant: Industrial Technology Research Institute, Hsinchu (TW)

(72) Inventor: Yi-Shou Tsai, Taipei City (TW)

(73) Assignee: Industrial Technology Research Institute, Hsinchu (TW)

(21) Appl. No.: 15/371,225

(22) Filed: Dec. 7, 2016

(30) Foreign Application Priority Data
Aug. 15, 2016 (TW) 105125896

(51) Int. Cl. H01L 27/32; H01L 51/52

(52) U.S. Cl. CPC H01L 27/322; H01L 51/5284; H01L 51/5203; H01L 27/3262; H01L 27/3246; H01L 51/5246; H01L 51/5253

(57) ABSTRACT

A display device includes a substrate, a plurality of pixel structures and a color filter layer. The substrate has a plurality of pixel regions thereon. The plurality of pixel structures are corresponding respectively disposed on the pixel regions, respectively. Each of the pixel structures includes an active device layer, a light absorption layer, an optical matching layer, a first transparent electrode, a light emitting layer and a second transparent electrode. The color filter layer covers the plurality of pixel structures and has a plurality of color filter elements correspondingly disposed in the plurality of pixel regions, respectively. The plurality of pixel structures are disposed between the substrate and the color filter layer.

### CROSS-REFERENCE TO RELATED FIELD APPLICATION

This application claims the priority benefits of Taiwan application serial no. 105125896, filed on Aug. 15, 2016. The entirety of the above-mentioned patent applications is hereby incorporated by reference herein.

### Technical Field

The disclosure relates to a display device.

### Background

A light emitting diode display is a display element utilizing the self-luminescent characteristics of light emitting materials to display. The luminescent structure of the light emitting diode display mainly includes a pair of electrodes and a light emitting layer between the electrodes. When a current flows through the light emitting layer via an anode and a cathode, electrons and holes are combined in the light emitting layer to generate excitons, so as to generate light beams of different colors based on material characteristics of the light emitting layer.

For a self-luminescent display, the display quality affected by the ambient light is an important factor need to be considered. The color purity is also a factor to affect the display quality. The display quality of high output luminance, high ambient contrast ratio and good color purity are required for a self-luminescent display.

### SUMMARY

An embodiment of the disclosure provides a display device including a substrate, a plurality of pixel structures and a color filter layer. The substrate has a plurality of pixel regions thereon. The plurality of pixel structures are correspondingly disposed on the plurality of pixel regions, respectively. Each of the pixel structures includes an active device layer, a light absorption layer, an optical matching layer, a first transparent electrode, a light emitting layer and a second transparent electrode. The active device layer is disposed on the substrate, the light absorption layer is disposed on the active device layer, the optical matching layer is disposed on the light absorption layer, the first transparent electrode is disposed on the optical matching layer, the light emitting layer is disposed on the first transparent electrode and the second transparent electrode is disposed on the light emitting layer. The color filter layer covers the plurality of pixel structures and has a plurality of color filter elements correspondingly disposed in the plurality of pixel regions, respectively. The plurality of pixel structures are disposed between the substrate and the color filter.

The foregoing will become better understood from a careful reading of a detailed description provided herein below with appropriate reference to the accompanying drawings.

### BRIEF DESCRIPTION OF THE DRAWINGS

FIG. 1 illustrates a display device according to an embodiment of the disclosure.

FIG. 2A illustrates a top view of the display device of FIG. 1.

FIG. 2B illustrates a top view of the display device of FIG. 1 and FIG. 7.

FIG. 3A to FIG. 3C illustrate a relationship between wavelength and emission intensity of a display device according to an embodiment of the disclosure.

FIG. 4A to FIG. 4C illustrate a relationship between wavelength and reflectance of a display device according to an embodiment of the disclosure.

FIG. 5 illustrates a display device according to another embodiment of the disclosure.

FIG. 6 illustrates a top view of the display device of FIG. 5 and FIG. 8.

FIG. 7 illustrates a display device according to another embodiment of the disclosure.

FIG. 8 illustrates a display device according to another embodiment of the disclosure.

### DETAILED DESCRIPTION OF DISCLOSED EMBODIMENTS

Below, exemplary embodiments will be described in detail with reference to accompanying drawings so as to be easily realized by a person having ordinary knowledge in the art. The inventive concept may be embodied in various foiiiis without being limited to the exemplary embodiments set forth herein. Descriptions of well-known parts are omitted for clarity, and like reference numerals refer to like elements throughout.

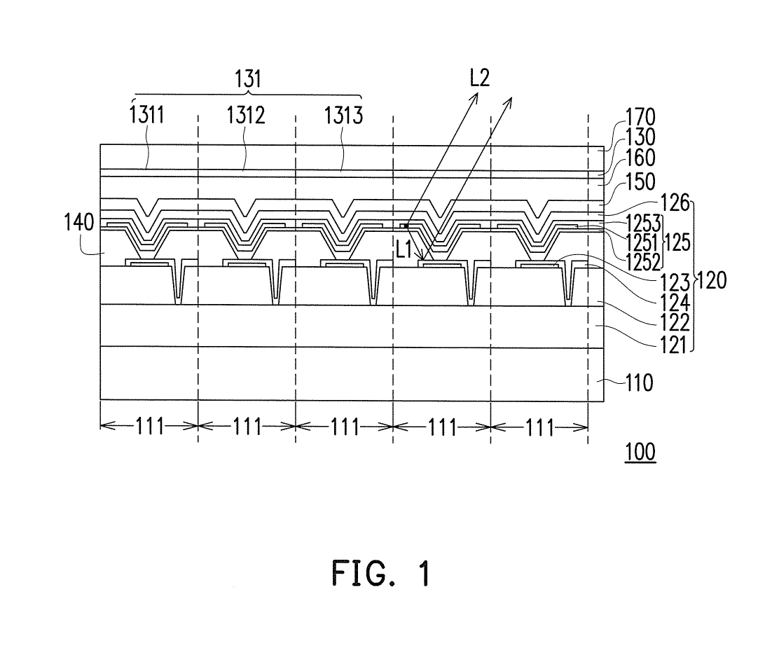

FIG. 1 illustrates a display device according to an embodiment of the disclosure. As shown in FIG. 1, a display device 100 includes a substrate 110, a plurality of pixel structures 120 and a color filter layer 130. The substrate 110 has a plurality of pixel regions 111 thereon. The plurality of pixel structures 120 are correspondingly disposed on the pixel regions 111, respectively. Each of the pixel structures 120 includes an active device layer 121, a light absorption layer 122, an optical matching layer 123, a first transparent electrode 124, a light emitting layer 125 and a second transparent electrode 126. The active device layer 121 is disposed on the substrate 110, the light absorption layer 122 is disposed on the active device layer 121, the optical matching layer 123 is disposed on the light absorption layer 122, the first transparent electrode 124 is disposed on the optical matching layer 123, the light emitting layer 125 is disposed on the first transparent electrode 124 and the second transparent electrode 126 is disposed on the light emitting layer 125. The color filter layer 130 covers the plurality of pixel structures 120 and has a plurality of color filter elements 131 correspondingly disposed in the plurality of pixel regions 111, respectively. The plurality of pixel structures 120 is disposed between the substrate 110 and the color filter layer 130.

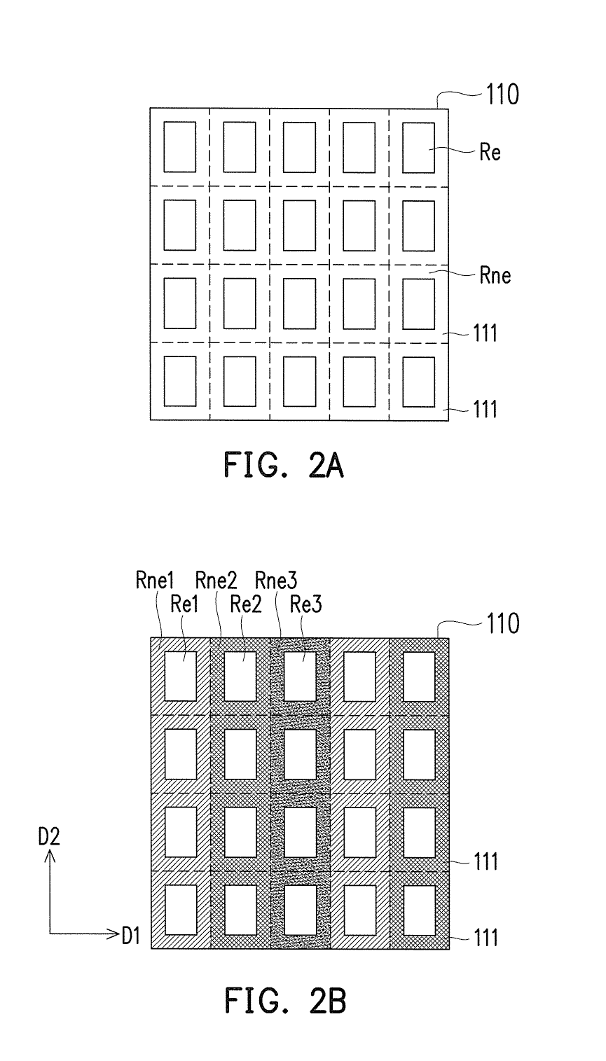

FIG. 2A illustrates a top view of the display device 100 of FIG. 1. FIG. 2A illustrates the substrate 110 and the plurality of pixel regions 111. The substrate 110 has a plurality of pixel regions 111 thereon. In this embodiment, the plurality of pixel regions are arranged in an array on the substrate. The plurality of pixel structures 120 and the plurality of color filter elements 131 are correspondingly disposed on the pixel regions 111, respectively. FIG. 2A also illustrates light emission regions Re and non-emission regions Rne of the display device 100. Each of the light emission regions Re is located in one of the pixel regions 111. The light emission regions Re of FIG. 2A are substantially located in the center of the pixel regions 111, but it's just an exemplary embodiment, the scope of the disclosure is not limited thereto.

The light emission region Re in one of pixel regions 111 is defined by the first transparent electrode 124, the light emitting layer 125 and the second transparent electrode 126 of the pixel region 111. The light emitting layer 125 disposed between the first transparent electrode 124 and the second transparent electrode 126 may emit light by applying a voltage to the electrodes and fonn the light emission region Re. The region excluding the light emission region Re in the pixel region 111 is non-emission region Rne.

In the present embodiment, the substrate 110 may be, but not limited to a flexible substrate, wherein the material of the flexible substrate may be polyimide (PI), complex of polyimide and inorganic material(hybrid PI), Polyethylene terephthalate (PET), Polyethersulfone (PES), polyacrylate (PA), Polyethylene naphthalatc (PEN), polycarbonate (PC), polynorbornene (PNB), polyetherimide (PEI), polyetheretherketone (PEEK), Cyclo olefin polymer (COP), PMMA, Glass Fiber Reinforced Plastic (GFRP) or Carbon Fiber Reinforced Polymer (CFRP), or the like. In another embodiment, the substrate 110 may be made of glass or other rigid materials. Alternately, the substrate 110 may also be a composite substrate made of a plurality of material layers for providing gas or vapor barrier functions, wherein the material layers may include at least one organic layer and/or at least one inorganic layer. The scope of the disclosure is not limited thereto.

The active device layer 121 comprises a thin film transistor (TFT), for instance. The thin film transistor may be an organic thin film transistor (OTFT). The light absorption layer 122 may be a black resin, for example, for absorbing external ambient light. Alternatively, the light absorption layer 122 may include a multi-layer structure formed by alternately stacking different film-layers, such as a low-reflectance multi-layer structure formed by alternately stacking a plurality of LiF layers and a plurality of Cr layers. The optical matching layer 123 may include a single layer or a multi-layer structure formed by alternately stacking different film-layers, such as a multi-layer structure formed by alternately stacking a plurality of SiO₂ and TiO₂ layers. The first transparent electrode 124 and the second transparent electrode 126 may be respectively an anode and a cathode for providing a current to the light emitting layer 125, so that the light emitting layer 125 may emit light beams L1 and L2. The first transparent electrode 124 and the second transparent electrode 126 may include indium tin oxide (ITO), indium zinc oxide (IZO), etc., but the scope of the disclosure is not limited thereto. The first transparent electrode 124 and the second transparent electrode 126 may be made of the same material or different materials. The light emitting layer 125 may be any organic light emitting layer suitable for an organic light emitting diode (OLED) display device, or an inorganic light emitting layer (or a quantum dot light emitting layer) suitable for a quantum dot light emitting diode (QLED) display device, for example. The color filter elements 131 may include photosensitive resin or thermosetting resin, but the scope of the disclosure is not limited thereto.

The light emitting layer 125 may be formed, by sequentially stacking a first carrier injection layer, a first carrier transmission layer, a second carrier blocking layer, an emission layer, a first carrier blocking layer, a second carrier transmission layer and a second carrier injection layer, from the first transparent electrode 124 to the second transparent electrode 126. The first carrier and the second carrier described in the embodiment may be considered as different types of carriers such as electron and hole. For example, the first carrier is an electron and the second carrier is an electric hole, or the first carrier is an electric hole and the second carrier is an electron. The scope of the disclosure is not limited thereto. In one embodiment of FIG. 1 the light emitting layer 125 includes an emission layer 1251, an electron transmission layer (ETL) 1252 and a hole transmission layer (HTL) 1253, wherein the emission layer 1251 is disposed between the electron transmission layer (ETL) 1252 and the hole transmission layer (HTL) 1253. The structure of the light emitting layer 125 is not limited to the present embodiment.

In another embodiment, the display device 100 further includes a pixel define layer (PDL) 140, a thin film encapsulation (TFE) layer 150, glue 160 and a cover 170. The plurality of pixel structures 120 of the display device 100 are defined by the pixel define layer (PDL) 140. The pixel define layer (PDL) 140 is disposed between the light emitting layer 125 and the light absorption layer 122. The optical matching layer 123 and the first transparent electrode 124 are disposed between the light absorption layer 122 and the pixel define layer (PDL) 140. The thin film encapsulation (TFE) layer 150 is disposed on the second transparent electrode 126, the glue 160 disposed on the thin film encapsulation (TFE) layer 150. The thin film encapsulation (TFE) layer 150 and the glue 160 are disposed between the second transparent electrode 126 and the color filter layer 130, the cover 170 is disposed on the color filter layer 130, and the color filter layer 130 is disposed between the glue 160 and the cover 170.

In the embodiment, the color filter layer 130 is formed on the cover 170 and the pixel structures 120, the pixel define layer (PDL) 140, and the thin film encapsulation (TFE) layer 150 are formed on the substrate 110 in sequence during the process of fabricating the display device 100. The color filter layer 130 on the cover 170 and the thin film encapsulation (TFE) layer 150 on the substrate 110 are bonded by the glue 160. Then the display device 100 is completed.

The pixel define layer (PDL) 140 may include photosensitive resin. The thin film encapsulation (TFE) layer 150 may include a multi-layer structure formed by stacking different inorganic films, such as a multi-layer structure foamed by alternately stacking a plurality of silicon nitride (SiNₓ) and silicon oxycarbide (SiOC) films. But the number of layers or the material constituting of the inorganic films is not limited to the present embodiment. In other embodiment, the thin film encapsulation layer 150 may include a single layer or a multi-layer structure formed by alternately stacking organic or inorganic films. The inorganic material includes, for instance, Al₂O₃, SiOₓ, SiNₓ, SiOₓN_{y} or SiOC. The organic material includes parylene, polymer or acrylic. It may be appropriately changed according to the actual design requirement. The glue 160 may include Epoxy resin, Urea resin, Melamine, Phenol resin, Acrylics, Butyl rubber, ethylene-vinyl acetate, nitriles, silicon rubber, styrene block copolymer. The scope of the disclosure is not limited thereto.

The cover 170 may be, but not limited to a flexible substrate, wherein the material of the flexible substrate may be polyimide (PI), complex of polyimide and inorganic material (hybrid PI), Polyethylene terephthalate (PET), Polyethersulfone (PES), polyacrylate(PA), Polyethylene naphthalatc (PEN), polycarbonate(PC), polynorbornene (PNB), polyetherimide (PEI), polyetheretherketone (PEEK), Cyclo olefin polymer (COP), PMMA, Glass Fiber Reinforced Plastic (GFRP) or Carbon Fiber Reinforced Polymer (CFRP), or the like. In another embodiment, the cover 170 may be made of glass or other rigid material. Alternately, the cover 170 may also be a composite substrate made of a plurality of material layers for providing gas or vapor barrier functions, wherein the material layers may include at least one organic layer and/or at least one inorganic layer. The scope of the disclosure is not limited thereto.

In this embodiment, to prevent the light beam L1 emitted downward from being absorbed by the light absorption layer 122, the optical matching layer 123 is disposed between the light absorption layer 122 and the first transparent electrode 124. In addition, with the optical matching layer 123 being matched with the light absorption layer 122, a portion of the light beam L1 emitted downward may be reflected by the optical matching layer 123 to maintain a top output luminance without reflecting a significant amount of the ambient light. Here, a refractive index of the light absorption layer 122 and a refractive index of the optical matching layer 123 are set to satisfy the condition of 0.008<[(n1−n2)/(n1+n2)]̂2<0.8, wherein n1 is the refractive index of the light absorption layer 122, and n2 is a refractive index of the optical matching layer 123. In this embodiment, the refractive index of the light absorption layer 122 is less than the refractive index of the optical matching layer 123. Namely, in this embodiment, the top output luminance and a reflectance of the ambient light are controlled by adjusting the refractive indices of the optical matching layer 123 and the light absorption layer 122, so as to increase an ambient contrast ratio of the display device 100. In the present embodiment, the color purity of the display device 100 also may be increased due to the disposition of color filter elements 131.

When the optical matching layer 123 includes a metal material, such as Al, Ag, or AlNd, etc., the refractive index of the light absorption layer 122 and the refractive index of the optical matching layer 123 satisfy the condition of 0.008<[(n1−n2)/(n1+n2)]̂2<0.8. Also, when the optical matching layer 123 includes a material such as Si, the refractive index of the light absorption layer 122 and the refractive index of the optical matching layer 123 satisfy the condition of 0.008<[(n1−n2)/(n1+n2)]̂2<0.3. Furthermore, when the optical matching layer 123 includes an organic material or a metal oxide, such as SiOₓ or Nb₂Oₓ, etc., the refractive index of the light absorption layer 122 and the refractive index of the optical matching layer 123 satisfy the condition of 0.008<[(n1−n2)/(n1+n2)]̂2<0.15.

Please refer to FIG. 1 again, in one pixel region 111, the color of the light emitted by the light emitting layer 125 of the pixel structure 120 is substantially the same as the filtered color of the color filter element 131 (the color that appears after the white color passes through the color filter element 131) in the same pixel region 111. The color of the light emitted by the light emitting layer 125 of a pixel structure 120 in one pixel region 111 may be the same as or different from the color of the light emitted by the light emitting layer 125 of its one or more neighboring the pixel structures 120.

FIG. 2B illustrates a top view of the display device 100 of FIG. 1. FIG. 2B illustrates a substrate 110, a plurality of pixel regions 111, light emission regions Re and non-emission regions Rne of the display device 100. In the embodiment, the color of the light emitted by the light emitting layer 125 of the pixel structure 120 is substantially the same as the filtered color of the color filter element 131 in the same pixel region 111. The light emitting layer 125 of the display device 100 includes a first light emitting layer (light emission region Re1) for emitting light of a first color, a second light emitting layer (light emission region Re2) for emitting light of a second color, and a third light emitting layer (light emission region Re3) for emitting light of a third color in different pixel regions of the plurality of pixel regions 111. The first light emitting layer, the second light emitting layer, and the third light emitting layer respectively correspond to three color filter elements, and the filtered colors of the three color filter element are respectively the same as the three colors of the light emitted by the light emitting layer 125, as show in FIG. 1, the three color filter elements are a first color filter element 1311, a second color filter element 1312, and a third color filter element 1313, respectively. The light emission regions Re1, Re2 and Re3 are arranged in sequence and repeatedly along a first direction D1 shown in FIG. 2B. The light emission regions Re1, Re2 and Re3 are arranged with the light emission regions of same light emitting color and repeatedly along a second direction D2, as shown in FIG. 2B. The first direction D1 is substantially perpendicular to the second direction D2. The non-emission region Rne in each pixel region 111 exhibit the filtered color of its corresponding color filter element 131 in the pixel region 111. FIG. 2B illustrates the arrangement of the non-emission regions of the first color Rne1, the non-emission regions of the second color Rne2 and the non-emission regions of the third color Rne3. In one embodiment, the first color, the second color and the third color are red, green and blue respectively. In other embodiments, the first color, the second color and the third color may be other colors, but the scope of the disclosure is not limited thereto. In addition, there are 3 kinds of pixel colors in the embodiment, but in other embodiments, the number of pixel colors may be greater or less than 3, but the scope of the disclosure is not limited thereto.

The arrangements of the pixels of the first color, the second color and the third color illustrated in the embodiments of FIG. 2A and FIG. 2B are strip-shaped. In other embodiments, the arrangement of the 3 pixel colors may be triangle-shaped or a mosaic arrangement, but the scope of the disclosure is not limited thereto. Pixel regions are categorized by their pixel arrangements. That is, pixel regions correspond to pixel arrangements, respectively. Color filter elements 131 also respectively correspond to the pixel arrangements. In a same pixel region, the filtered color of the color filter element 131 is substantially the same as the color of the light emitted by the light emitting layer 125.

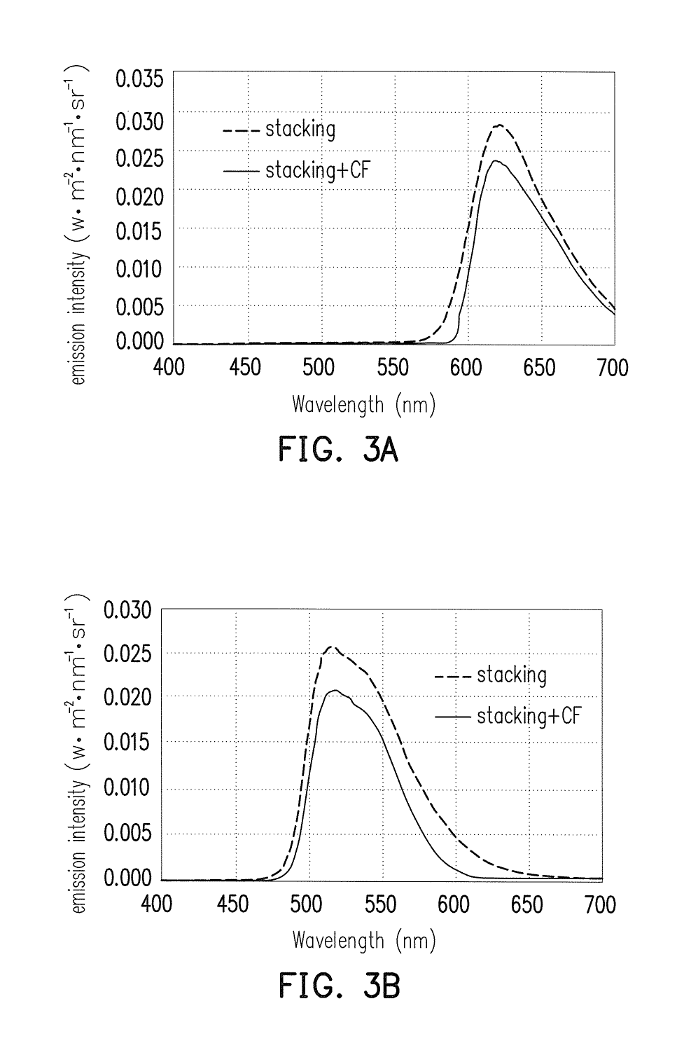

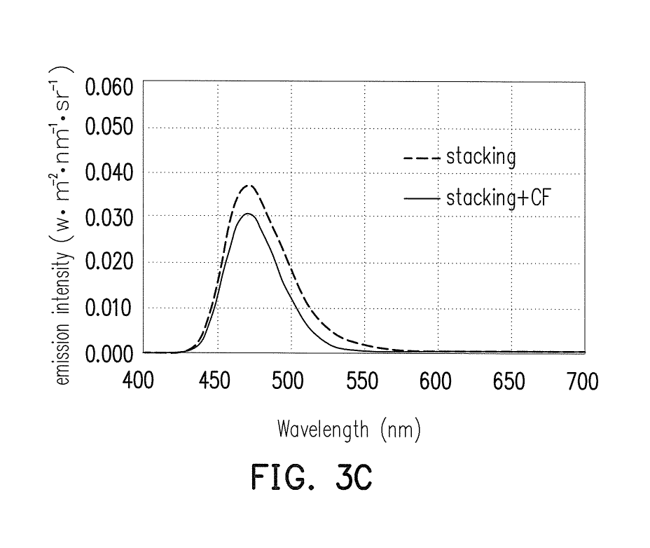

FIG. 3A to FIG. 3C illustrate a relationship between wavelength and emission intensity of a display device 100 according to an embodiment of the disclosure, which illustrate the simulation results of the emission intensity of the display device 100. Wherein FIG. 3A illustrates a relationship between the wavelength and the emission intensity of red light. The horizontal axis represents wavelength and the wavelength unit is nanometer. The vertical axis represents emission intensity and the unit is W·m⁻²·nm⁻¹·sf⁻¹. The dotted line represents the relationship between wavelength and emission intensity without adding the color filter (CF) layer 130 in the embodiment. The solid line represents the relationship between wavelength and emission intensity with adding the color filter (CF) layer 130 in the embodiment. In FIG. 3A, the filtered color of the color filter layer 130 is red. The disposition of the color filter layer 130 may narrow the full width at half maximum (FWHM) of the spectrum of output light, and raise the red color purity of the display device 100. Similar to FIG. 3A, FIG. 3B illustrate a relationship between the wavelength and the emission intensity of green light, FIG. 3C illustrate a relationship between the wavelength and the emission intensity of blue light. As shown in FIG. 3B and FIG. 3C, the disposition of the color filter (CF) layer 130 (In FIG. 3B and FIG. 3C, the filtered colors of the color filter layer 130 are green and blue, respectively) narrow the full width at half maximum (FWHM) of the spectrum of output light, and raise the green color purity and the blue color purity of the display device 100. Therefore, the color purity of the display device 100 may be increased.

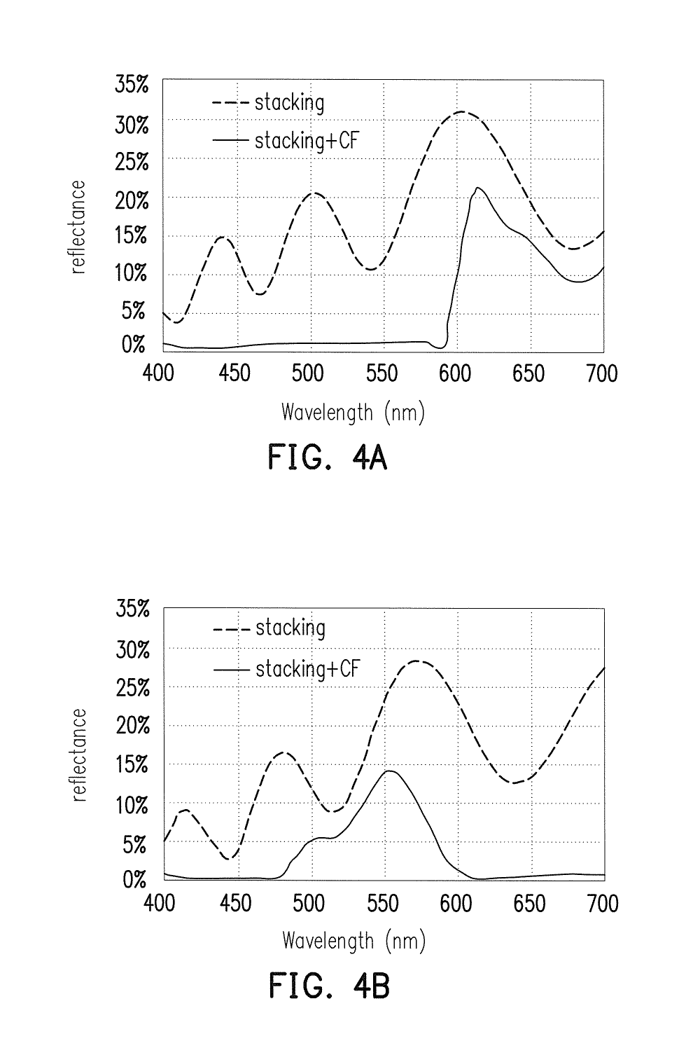

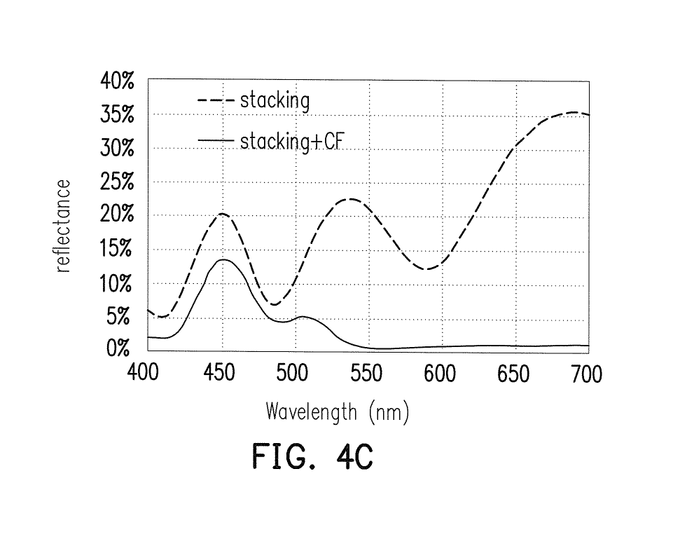

FIG. 4A to 4C illustrate a relationship between wavelength and reflectance of a display device according to an embodiment of the disclosure, which illustrate the simulation results of the reflectance of the display device 100. The reflectance means the ratio of the ambient light incident to the display device 100 to the reflected light of the ambient light from the display device 100. FIG. 4A illustrates a relationship between the wavelength and the reflectance of red light. The horizontal axis represents wavelength and the wavelength unit is nanometer. The vertical axis represents reflectance. The dotted line represents the relationship between the wavelength and the reflectance without adding the color filter layer 130 in the embodiment. The solid line represents the relationship between the wavelength and the reflectance of the display device with adding the color filter layer 130 in the embodiment. In FIG. 4A, the filtered color of the color filter layer 130 is red. The disposition of the color filter layer 130 may reduce the reflectance of the red light and raise the ambient contrast ratio of the display device 100. Similar to FIG. 4A, FIG. 4B illustrates a relationship between the wavelength and the reflectance of green light, FIG. 4C illustrates a relationship between the wavelength and the reflectance of blue light. As shown in FIG. 4B and FIG. 4C, the disposition of the color filter layer 130 (In FIG. 4B and FIG. 4C, the filtered colors of the color filter layer 130 are green and blue, respectively) reduces the reflectance of the green light and the blue light. Therefore, the ambient contrast ratio of the display device 100 may be raised.

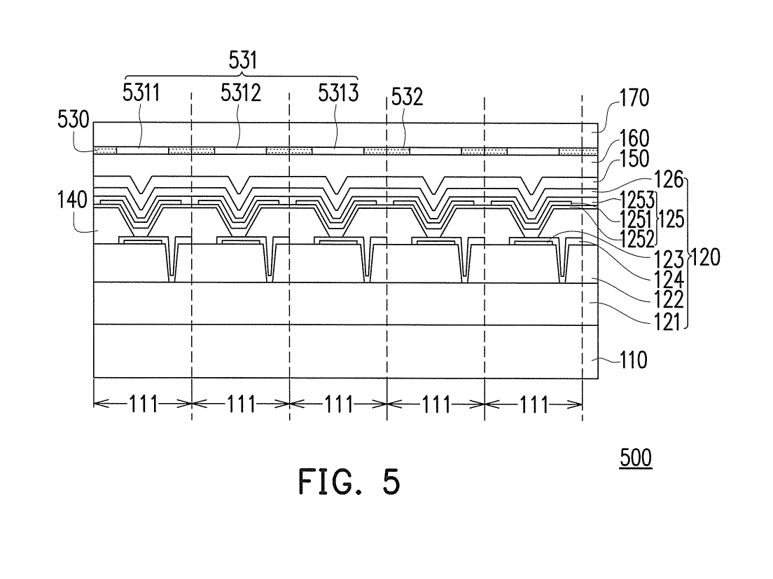

FIG. 5 illustrates a display device according to another embodiment of the disclosure. As shown in FIG. 5, a display device 500 is similar to the display device 100 in the previous embodiment. The same or similar reference numbers used in each of the following exemplary embodiments represent the same or the like elements, and thus descriptions of the same or the like elements will not be repeatedly provided hereinafter. The difference between the two display devices is that the color filter layer 130 of the display device 500 further includes a plurality of black matrix (BM) structures 532, in addition to the plurality of color filter element 531. As shown in FIG. 5, the display device 500 includes the substrate 110, the plurality of pixel structures 120 and the color filter layer 530. The substrate 110 has a plurality of pixel regions 111 thereon. The plurality of pixel structures 120 are correspondingly disposed on the pixel regions 111, respectively. Each of the pixel structures 120 includes the active device layer 121, the light absorption layer 122, the optical matching layer 123, the first transparent electrode 124, the light emitting layer 125 and the second transparent electrode 126. The active device layer 121 is disposed on the substrate 110, the light absorption layer 122 is disposed on the active device layer 121, the optical matching layer 123 is disposed on the light absorption layer 122, the first transparent electrode 124 is disposed on the optical matching layer 123, the light emitting layer 125 is disposed on the first transparent electrode 124 and the second transparent electrode 126 is disposed on the light emitting layer 125. The color filter layer 530 covers the plurality of pixel structures 120 and has a plurality of color filter elements 531 and a plurality of black matrix (BM) structures 532. The plurality of color filter elements 531 are correspondingly disposed in the plurality of pixel regions 111, respectively. The disposition of the black matrix (BM) structures 532 may further reduce the reflectance of the ambient light incident to the display device and increase the ambient contrast ratio.

FIG. 2A also illustrates a top view of the display device 500 of FIG. 5. FIG. 2A illustrates the substrate 110 and the plurality of pixel regions 111. The substrate 110 has a plurality of pixel regions 111 thereon. The pixel regions are arranged in an array on the substrate, and comprises light emission regions Re and non-emission regions Rne. The light emission regions are located in the pixel regions. The regions excluding the light emission regions Re in the pixel regions 111 are non-emission regions Rne. As shown in FIG. 5, each of the color filter elements 531 is correspondingly disposed in one of the light emission regions Re of a same pixel region, while each of the black matrix (BM) structures 532 is correspondingly disposed in one of the non-emission regions Rne of the same pixel region. The light emission region Re of FIG. 2A is substantially located at the center of the pixel region 111, but it's only an exemplary embodiment, the scope of the disclosure is not limited thereto. The light emission region Re may be located at any position in the pixel region.

The light emission region Re in one pixel region 111 is defined by the first transparent electrode 124, the light emitting layer 125 and the second transparent electrode 126 in the pixel region. The light emitting layer 125 disposed between the first transparent electrode 124 and the second transparent electrode 126 may emit light and form the light emission region Re. In each pixel region 111, the region excluding the light emission region Re is a non-emission region Rne.

In the pixel regions 111, the shape or the size of the color filter elements 131 may be designed according to the actual demands. The color filter elements 531 in each pixel region 111 substantially cover all the lighting area of the light emission region Re in the pixel region 111. The region excluding the color filter elements in the color filter layer 530 of each pixel region 111 is the black matrix (BM) structure 532.

In the present embodiment, the substrate 110 may be, but not limited to a flexible substrate, wherein the material of the flexible substrate may be polyimide (PI), complex of polyimide and inorganic material(hybrid PI), Polyethylene terephthalate (PET), Polyethersulfone (PES), polyacrylate (PA), Polyethylene naphthalatc (PEN), polycarbonate (PC), polynorbornene (PNB), polyetherimide (PEI), polyetheretherketone (PEEK), Cyclo olefin polymer (COP), PMMA, Glass Fiber Reinforced Plastic (GFRP) or Carbon Fiber Reinforced Polymer (CFRP), or the like. In another embodiment, the substrate 110 may be made of glass or other rigid material. Alternately, the substrate 110 may also be a composite substrate made of a plurality of material layers for providing gas or vapor barrier functions, wherein the material layers may include at least one organic layer and/or at least one inorganic layer. The scope of the disclosure is not limited on the type and the composition of the substrate 110.

The active device layer 121 comprises a thin film transistor (TFT), for instance. The thin film transistor may be organic thin film transistor (OTFT). The light absorption layer 122 is a black resin, for example, for absorbing external ambient light. Alternatively, the light absorption layer 122 may include a multi-layer structure formed by alternately stacking different layers, such as a low reflectance multi-layer structure formed by alternately stacking a plurality of LiF layers and a plurality of Cr layers. The optical matching layer 123 may include a single layer or a multi-layer structure foiiiied by alternately stacking different films, such as a multi-layer structure formed by alternately stacking a plurality of SiO2 and TiO2 layers. The first transparent electrode 124 and the second transparent electrode 126 may be respectively an anode and a cathode that provide a current to the light emitting layer 125, so that the light emitting layer 125 may emit light beams LI and L2. The first transparent electrode 124 and the second transparent electrode 126 may include indium tin oxide (ITO), indium zinc oxide (IZO), etc. The disclosure is not limited thereto. The first transparent electrode 124 and the second transparent electrode 126 may be made of the same material or different materials. The light emitting layer 125 may be any organic light emitting layer suitable for an organic light emitting diode (OLED) display device, or an inorganic light emitting layer (or a quantum dot light emitting layer) suitable for a quantum dot light emitting diode (QLED) display device, for example. The color filter elements 131 may include photosensitive resin or thermosetting resin, but the scope of the disclosure is not limited thereto.

The light emitting layer 125 is formed by sequentially stacking a first carrier injection layer , a first carrier transmission layer, a second carrier blocking layer, an emission layer, a first carrier blocking layer, a second carrier transmission layer and a second carrier injection layer from the first transparent electrode 124 to the second transparent electrode 126. The first carrier and the second carrier described in the embodiment may be considered as different types of carriers such as the first carrier is an electron and the second carrier is an electric hole, or the first carrier is an electric hole and the second carrier is an electron. The scope of the disclosure is not limited thereto, which may be adjustable according to demands. In one embodiment of FIG. 5, the light emitting layer 125 includes an emission layer 1251, an electron transmission layer (ETL) 1252 and a hole transmission layer (HTL) 1253, wherein the emission layer 1251 is disposed between the electron transmission layer (ETL) 1252 and the hole transmission layer (HTL) 1253. The present composition of the light emitting layer 125 is not limited in the embodiments of the disclosure.

In another embodiment, the display device 500 further includes a pixel define layer (PDL) 140, a thin film encapsulation (TFE) layer 150, glue 160 and a cover 170. The plurality of pixel structures 120 of the display device 500 are defined by the pixel define layer (PDL) 140. The pixel define layer (PDL) 140 is disposed between the light emitting layer 125 and the light absorption layer 122. The optical matching layer 123 and the first transparent electrode 124 are disposed between the light absorption layer 122 and the pixel define layer (PDL) 140. The thin film encapsulation (TFE) layer 150 is disposed on the second transparent electrode 126, and the glue 160 is disposed on the thin film encapsulation (TFE) layer 150. The thin film encapsulation (TFE) layer 150 and the glue 160 are disposed between the second transparent electrode 126 and the color filter layer 530, the cover 170 is disposed on the color filter layer 530, and the color filter layer 530 is disposed between the glue 160 and the cover 170.

The pixel define layer (PDL) 140 may include photosensitive resin. The thin film encapsulation (TFE) layer 150 may include a multi-layer structure formed by stacking different inorganic films, such as a multi-layer structure formed by alternately stacking a plurality of silicon nitride (SiNₓ) and silicon oxycarbide (SiOC) films. But the number of layers or the material constituting of the inorganic films is not limited in the present embodiment. In other embodiments, the thin film encapsulation layer 150 may include a single layer or a multi-layer structure formed by alternately stacking organic or inorganic films. The inorganic material includes, for instance, Al₂O₃, SiOₓ, SiN_{X}, SiO_{X}N_{y} or SiOC. The organic material includes parylene, polymer or acrylic. It may be appropriately changed according to the actual design requirement. The glue 160 may include Epoxy resin, Urea resin, Melamine, Phenol resin, Acrylics, Butyl rubber, ethylene-vinyl acetate, nitriles, silicon rubber, styrene block copolymer. The scope of the disclosure is not limited thereto.

The cover 170 may be, but not limited to a flexible substrate, wherein the material of the flexible substrate may be polyimide(PI), complex of polyimide and inorganic material(hybrid PI), Polyethylene terephthalate (PET), Polyethersulfone (PES), polyacrylate (PA), Polyethylene naphthalatc (PEN), polycarbonate (PC), polynorbornene (PNB), polyetherimide (PEI), polyetheretherketone (PEEK), Cyclo olefin polymer (COP), PMMA, Glass Fiber Reinforced Plastic(GFRP) or Carbon Fiber Reinforced Polymer(CFRP), or the like. In another embodiment, the cover 170 may be made of glass or other rigid material. Alternately, the cover 170 may also be a composite substrate made of a plurality of material layers for providing gas/vapor barrier functions, wherein the material layers may include at least one organic layer and/or at least one inorganic layer. The scope of the disclosure is not limited thereto.

In this embodiment, to prevent the light beam L1 emitted downward from being absorbed by the light absorption layer 122, the optical matching layer 123 is disposed between the light absorption layer 122 and the first transparent electrode 124. In addition, with the optical matching layer 123 being matched with the light absorption layer 122, a portion of the light beam L1 emitted downward may be reflected by the optical matching layer 123 to maintain an upward output luminance without reflecting a significant amount of the ambient light. Here, a refractive index of the light absorption layer 122 and a refractive index of the optical matching layer 123 are set to satisfy the condition of 0.008<[(n1−n2)/(n1+n2)]̂2<0.8, wherein n1 is the refractive index of the light absorption layer 122, and n2 is a refractive index of the optical matching layer 123. In this embodiment, the refractive index of the light absorption layer 122 is less than the refractive index of the optical matching layer 123. In other words, in this embodiment, the upward top output luminance and a reflectance of the ambient light are controlled by adjusting the refractive indices of the optical matching layer 123 and the light absorption layer 122, so as to raise an ambient contrast ratio of the display device 500. In the present embodiment, the color purity of the display device 500 also may be raised due to the disposition of the color filter elements 531.

When the optical matching layer 123 includes a metal material, such as Al, Ag, or AlNd, etc., the refractive index of the light absorption layer 122 and the refractive index of the optical matching layer 123 satisfy the condition of 0.008<[(n1−n2)/(n1+n2)]̂2<0.8. Also, when the optical matching layer 123 includes a material such as Si, the refractive index of the light absorption layer 122 and the refractive index of the light matching layer 123 satisfy the condition of 0.008<[(n1−n2)/(n1+n2)]̂2<0.3. Furtheimore, when the optical matching layer 123 includes an organic material or a metal oxide, such as SiOₓ or Nb₂Oₓ, etc., the refractive index of the light absorption layer 122 and the refractive index of the optical matching layer 123 satisfy the condition of 0.008<[(n1−n2)/(n1+n2)]̂2<0.15.

Please refer to FIG. 5 again, in an exemplary embodiment, the color of the light emitted by the light emitting layer 125 of each pixel structure 120 in the plurality of pixel regions 111 is substantially the same as the filtered color of the color filter element 531(the color that appears after the white color passes through the color filter element 531) corresponding to the same pixel region 111. The color of the light emitted by the light emitting layer 125 of one pixel structure 120 in one pixel region 111 may be the same as or different from the color of the light emitted by the light emitting layer 125 of the pixel structure 120 in one or more neighboring pixel regions 111.

In the pixel regions 111, the shape or the size of the color filter elements 531 may be designed according to the actual demands. The color filter elements 531 in each pixel region 111 substantially cover all the lighting areas of the light emission region Re. In each pixel region 111, the area excluding the color filter elements 531 is a black matrix (BM) structure 532.

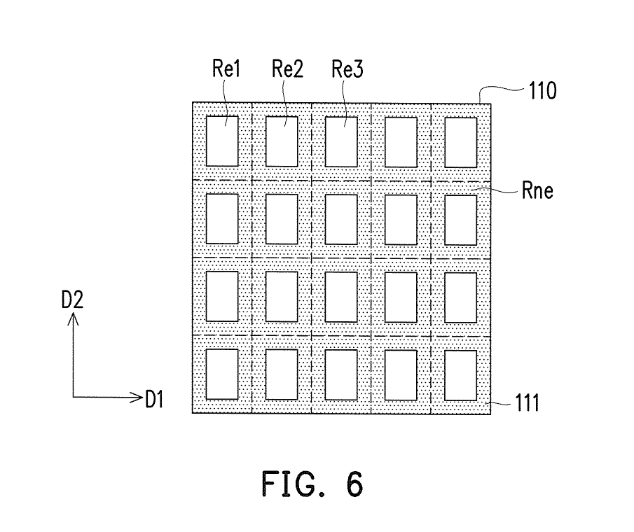

FIG. 6 illustrates a top view of the display device 500 of FIG. 5. FIG. 6 illustrates a substrate 110, a plurality of pixel regions 111, light emission regions Re and non-emission regions Rne of the display device 500 in an embodiment. In the embodiment, the color of the light emitted by the light emitting layer 125 of each pixel structure 120 in the plurality of pixel regions 111 is substantially the same as the filtered color of the color filter element 531 corresponding to the same pixel region 111. In this embodiment, the light emitting layer 125 of the display device 500 includes a first color light emitting layer (light emission region Re1) for emitting light of a first color, a second color light emitting layer (light emission region Re2) for emitting light of a second color, and a third color light emitting layer (light emission region Re3) for emitting light of a third color in different pixel regions 111. The first color light emitting layer, the second color light emitting layer, and the third color light emitting layer correspond respectively to three color filter elements having three filtered colors that are the same as the colors of the light emitted by the three color light emitting layers, respectively. As shown in FIG. 5, the color filter elements 531 may include a first color filter element 5311, a second color filter element 5312, and a third color filter element 5313. The light emission regions Re1, Re2 and Re3 are arranged in sequence and repeatedly along a first direction D1 in FIG. 6. The light emission regions Re1, Re2 and Re3 are arranged with the light emission regions of same light emitting color and repeatedly along a second direction D2, as shown in FIG. 6. The first direction D1 is substantially perpendicular to the second direction D2. The non-emission regions Rne in each pixel region 111 exhibit the black color due to the disposition of the black matrix structures. The non-emission regions of the first color Rne1, the non-emission regions of the second color Rne2 and the non-emission regions of the third color Rne3 are as shown in FIG. 6. In one embodiment, the first color, the second color and the third color may be red, green and blue, respectively. In other embodiments, the first color, the second color and the third color may be other colors, the scope of the disclosure is not limited thereto. In addition, there are 3 pixel colors in the embodiment, but in other embodiments, the pixel colors may be more or less than 3, the scope of the disclosure is not limited thereto.

The arrangements of the pixels of the first color, the second color and the third color illustrated in the embodiment of FIG. 6 are strip-shaped. In other embodiments (not shown), the arrangement of the 3 pixel colors may be triangle-shaped or a mosaic arrangement, but the scope of the disclosure is not limited thereto. Pixel regions are categorized by their pixel arrangements. That is, pixel regions correspond to pixel arrangements, respectively. Color filter elements 131 also respectively correspond to the pixel arrangements. In a same pixel region, the filtered color of the color filter element 131 is substantially the same as the color of the light emitted by the light emitting layer 125.

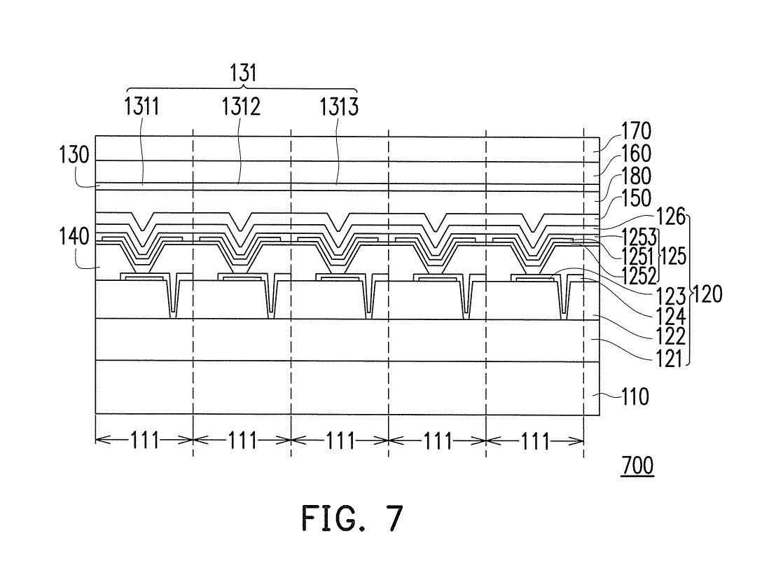

FIG. 7 illustrates a display device according to another embodiment of the disclosure. As shown in FIG. 7, a display device 700 is similar to the display device 100 in the aforementioned embodiment. The same or similar reference numbers used in each of the following exemplary embodiments represent the same or the like elements, and thus descriptions of the same or the like elements will not be repeatedly provided hereinafter. The difference between the two display devices is that the color filter layer 130 of the display device 700 is disposed between the thin film encapsulation (TFE) layer 150 and the glue 160.

As shown in FIG. 7, a display device 700 includes a substrate 110, a plurality of pixel structures 120 and a color filter layer 530. The substrate 110 has a plurality of pixel regions 111 thereon. The plurality of pixel structures 120 are respectively disposed on corresponding pixel regions 111. Each of the pixel structures 120 includes an active device layer 121, a light absorption layer 122, an optical matching layer 123, a first transparent electrode 124, a light emitting layer 125 and a second transparent electrode 126. The active device layer 121 is disposed on the substrate 110, the light absorption layer 122 is disposed on the active device layer 121, the optical matching layer 123 is disposed on the light absorption layer 122, the first transparent electrode 124 is disposed on the optical matching layer 123, the light emitting layer 125 is disposed on the first transparent electrode 124 and the second transparent electrode 126 is disposed on the light emitting layer 125. The color filter layer 130 covers the plurality of pixel structures 120 and has a plurality of color filter elements 131. The plurality of color filter elements 131 are correspondingly disposed in the plurality of pixel regions 111. The display device 700 further includes the pixel define layer (PDL) 140, the thin film encapsulation (TFE) layer 150, the glue 160, the cover 170 and a planarization layer 180. The plurality of pixel structures 120 of the display device 700 are defined by the pixel define layer (PDL) 140. The pixel define layer (PDL) 140 is disposed between the light emitting layer 125 and the light absorption layer 122. The optical matching layer 123 and the first transparent electrode 124 are disposed between the light absorption layer 122 and the pixel define layer (PDL) 140. The thin film encapsulation (TFE) layer 150 is disposed on the second transparent electrode 126. The planarization layer 180 is disposed on the thin film encapsulation (TFE) layer 150 and may make the surface more planar, the color filter layer 130 is disposed on the planarization layer 180, the glue 160 is disposed on the color filter layer 130, the cover 170 is disposed on the glue 160. The color filter layer 130 is disposed between the planarization layer 180 and the glue 160. The thin film encapsulation (TFE) layer 150, the planarization layer 180, the color filter layer 130 and the glue 160 are disposed between the second transparent electrode 126 and the cover 170.

In the embodiment of FIG.7, the color filter layer 130 is foi ned on the substrate 110, and then bonding the cover is performed during the process of fabricating the display device 700. Therefore, after the pixel structures 120, the pixel define layer (PDL) 140, the thin film encapsulation (TFE) layer 150, the planarization layer 180 and the color filter layer 130 are sequentially formed on the substrate 110, the color filter layer 130 and the cover 170 are bonded with the glue 160. Thereby, fabricating the display device 700 is done.

Please refer to FIG. 7 again. In a same pixel region 111, the color of the light emitted by the light emitting layer 125 of the pixel structure 120 is substantially the same as the filtered color of the color filter element 131 (the color that appears after the white color passes through the color filter element 131). The color of the light emitted by the light emitting layer 125 of a pixel structure 120 may be the same as or different from the color of the light emitted by the light emitting layer 125 of its one or more neighboring pixel structures 120.

Please refer to FIG. 2B again, FIG. 2B also illustrates a top view of the display device 700 of FIG. 7. FIG. 2B illustrates the substrate 110, the plurality of pixel regions 111, the light emission region Re and the non-emission region Rne of the display device 700. In the embodiment, the color of the light emitted by the light emitting layer 125 of the pixel structure 120 is substantially the same as the filtered color of the color filter element 131 in a same pixel region 111. The light emitting layer 125 of the display device 700 includes a first color light emitting layer (light emission region Re1) for emitting light of a first color, a second color light emitting layer (light emission region Re2) for emitting light of a second color, and a third color light emitting layer (light emission region Re3) for emitting light of a third color, and the three color light emitting layers are in different pixel regions 111. The first color light emitting layer, the second color light emitting layer, and the third color light emitting layer correspond respectively to three color filter elements having three filtered colors that are the same as the colors of the light emitted by the three color light emitting layers, respectively. As shown in FIG. 7, the three color filter elements are a first color filter element 1311, a second color filter element 1312, and a third color filter element 1313, respectively. The light emission regions Re1, Re2 and Re3 are arranged in sequence and repeatedly along a first direction D1 shown in FIG. 2B. The light emission regions Re1, Re2 and Re3 are arranged with the light emission regions of same light emitting color and repeatedly along a second direction D2, as shown in FIG. 2B. The first direction D1 is substantially perpendicular to the second direction D2. The non-emission region Rne in each pixel region 111 exhibits the filtered color of its corresponding color filter element 131 in the pixel region 111. The arrangements of the non-emission regions of the first color Rne1, the non-emission regions of the second color Rne2 and the non-emission regions of the third color Rne3 are as shown in FIG. 2. In one embodiment, the first color, the second color and the third color are red, green and blue respectively. In other embodiments, the first color, the second color and the third color may be other colors, but the scope of the disclosure is not limited thereto. In addition, there are 3 kinds of pixel colors in the embodiment, but in other embodiments, the pixel colors may be more or less than 3, the scope of the disclosure is not limited thereto.

In one embodiment, the arrangements of the pixels of the first color, the second color and the third color are strip-shaped. In other embodiments (not shown), the arrangement of the 3 pixel colors may be triangle-shaped or a mosaic arrangement, but the scope of the disclosure is not limited thereto. Pixel regions are categorized by their pixel arrangements. That is, pixel regions correspond to pixel arrangements, respectively. Color filter elements 131 also respectively correspond to the pixel arrangements. In a same pixel region, the filtered color of the color filter element 131 is substantially the same as the color of the light emitted by the light emitting layer 125.

The substrate 110, the active device layer 121, the light absorption layer 122, the optical matching layer 123, the first transparent electrode 124, the light emitting layer 125, the second transparent electrode 126, the color filter layer 130, the pixel the cover 170 of the display device 700 are the same as those of the display device 100 in the aforementioned embodiments, and thus descriptions of the same or the like elements will not be repeatedly provided hereinafter.

As the structure of the display device 700, the phenomenon that the light emitted by the light emitting layer 125 from one pixel region is emitted from neighboring pixel regions may be reduced, and the crosstalk between pixels may be avoided.

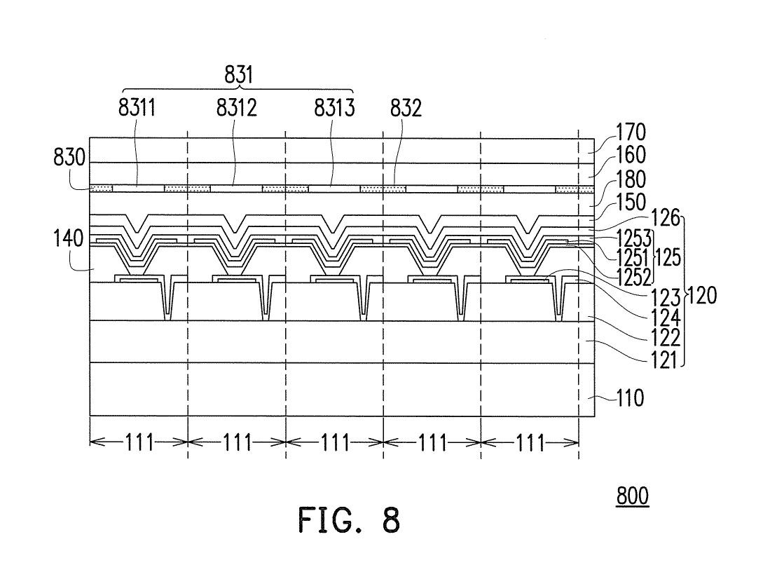

FIG. 8 illustrates a display device according to another embodiment of the disclosure. As shown in FIG. 8, a display device 800 is similar to the display device 700 in the previous embodiment. The same or similar reference numbers used in each of the following exemplary embodiments represent the same or the like elements, and thus descriptions of the same or the like elements will not be repeatedly provided hereinafter. The difference between the two display devices is that the color filter layer 830 of the display device 800 further includes a plurality of black matrix (BM) structures 832 except the plurality of color filter element 831. As shown in FIG. 8, the display device 800 includes the substrate 110, the plurality of pixel structures 120 and a color filter layer 830. The substrate 110 has a plurality of pixel regions 111 thereon. The plurality of pixel structures 120 are correspondingly disposed on the pixel regions 111, respectively. Each of the pixel structures 120 includes the active device layer 121, the light absorption layer 122, the optical matching layer 123, the first transparent electrode 124, the light emitting layer 125 and the second transparent electrode 126. The active device layer 121 is disposed on the substrate 110, the light absorption layer 122 is disposed on the active device layer 121, the optical matching layer 123 is disposed on the light absorption layer 122, the first transparent electrode 124 is disposed on the optical matching layer 123, the light emitting layer 125 is disposed on the first transparent electrode 124 and the second transparent electrode 126 is disposed on the light emitting layer 125. The color filter layer 830 covers the plurality of pixel structures 120 and has a plurality of color filter elements 831 and a plurality of black matrix (BM) structures 832. The plurality of color filter elements 831 are correspondingly disposed in the plurality of pixel regions 111, respectively. The display device 800 further includes the pixel define layer (PDL) 140, the thin film encapsulation (TFE) layer 150, the glue 160, the cover 170 and the planarization layer 180. The plurality of pixel structures 120 of the display device 800 are defined by the pixel define layer (PDL) 140. The pixel define layer (PDL) 140 is disposed between the light emitting layer 125 and the light absorption layer 122. The optical matching layer 123 and the first transparent electrode 124 are disposed between the light absorption layer 122 and the pixel define layer (PDL) 140. The thin film encapsulation (TFE) layer 150 is disposed on the second transparent electrode 126. The planarization layer 180 is disposed on the thin film encapsulation (TFE) layer 150 and may make the surface more planar. The color filter layer 830 is disposed on the glue 160 is disposed on the planarization layer 180, the glue 160 is disposed on the color filter layer 830, and the cover 170 is disposed on the glue 160. The color filter layer 830 is disposed between the planarization layer 180 and the glue 160. The thin film encapsulation (TFE) layer 150, the planarization layer 180, the color filter layer 830 and the glue 160 are disposed between the second transparent electrode 126 and the cover 170. The disposition of the black matrix (BM) structures 832 may further reduce the reflectance of the ambient light incident to the display device and raise the ambient contrast ratio.

Please refer to FIG. 8 again, in one pixel region 111, the color of the light emitted by the light emitting layer 125 of each of the plurality of the pixel structures 120 is substantially the same as the filtered color of the color filter element 831the color that appears after the white color passes through the color filter element 831) in the same pixel region 111. The color of the light emitted by the light emitting layer 125 of a pixel structure 120 in one pixel region 111 may be the same as or different from the color of the light emitted by the light emitting layer 125 of its one or more neighboring the pixel structures 120.

Please refer to FIG. 6 again. FIG. 6 also illustrates a top view of the display device 800 of FIG. 8. FIG. 6 illustrates a substrate 110, a plurality of pixel regions 111, light emission regions Re and non-emission regions Rne of the display device 800. In one embodiment, the color of the light emitted by the light emitting layer 125 of each pixel structure 120 is substantially the same as the filtered color of the color filter element 831 in a same pixel region 111. The light emitting layer 125 of the display device 800 includes a first color light emitting layer (light emission region Re1) for emitting light of first color, a second color light emitting layer (light emission region Ret) for emitting light of second color, and a third color light emitting layer (light emission region Re3) for emitting light of third color in different pixel regions 111, and the three color light emitting layers are in different pixel regions 111. The first color light emitting layer, the second color light emitting layer, and the third color light emitting layer correspond respectively to three color filter elements having three filtered colors that are the same as the colors of the light emitted by the three color light emitting layers, respectively. As shown in FIG. 8, the color filter elements 831 may include a first color filter element 8311, a second color filter element 8312, and a third color filter element 8313. The light emission regions Re1, Re2 and Re3 are arranged in sequence and repeatedly along a first direction D1 in FIG. 6. The light emission regions Rel, Re2 and Re3 are arranged with the light emission regions of same light emitting color and repeatedly along a second direction D2, as shown in FIG. 6. The first direction D1 is substantially perpendicular to the second direction D2. The non-emission region Rne in each pixel region 111 exhibit the black color due to the disposition of the black matrix structure. The non-emission regions of the first color Rne1, the non-emission regions of the second color Rne2 and the non-emission regions of the third color Rne3 are as shown in FIG. 6. In one embodiment, the first color, the second color and the third color may be red, green and blue, respectively. In other embodiments, the first color, the second color and the third color may be other colors, the scope of the disclosure is not limited thereto. In addition, there are 3 pixel colors in the embodiment, but in other embodiments of the display device 800, the pixel colors may be more or less than 3, the scope of the disclosure is not limited thereto.

In one embodiment, the arrangements of the pixels of the first color, the second color and the third color are strip-shaped. In other embodiments (not shown), the arrangement of the 3 pixel colors may be triangle-shaped or a mosaic arrangement, but the scope of the disclosure is not limited thereto. Pixel regions are categorized by their pixel arrangements. That is, pixel regions correspond to pixel arrangements, respectively. Color filter elements 831 also respectively correspond to the pixel arrangements. In a same pixel region, the filtered color of the color filter element 831 is substantially the same as the color of the light emitted by the light emitting layer 125.

According to the aforementioned embodiments of the disclosure, the embodiments provide displays with a high output luminance, a high ambient contrast ratio and a high color purity.

It will be apparent to those skilled in the art that various modifications and variations can be made to the disclosed embodiments. It is intended that the specification and examples be considered as exemplary embodiments only, with a scope of the disclosure being indicated by the following claims and their equivalents.

What is claimed is:

1. A display device, comprising:
a substrate, having a plurality of pixel regions thereon;
a plurality of pixel structures, correspondingly disposed on the plurality of pixel regions, respectively, wherein each of the plurality of pixel structures comprises:
an active device layer, disposed on the substrate;
a light absorption layer, disposed on the active device layer;
an optical matching layer, disposed on the light absorption layer;
a first transparent electrode, disposed on the optical matching layer;
a light emitting layer, disposed on the first transparent electrode; and
a second transparent electrode, disposed on the light emitting layer; and
a color filter layer, covering the plurality of pixel structures, and having a plurality of color filter elements correspondingly disposed in the plurality of pixel regions, respectively, wherein the plurality of pixel structures are disposed between the substrate and the color filter layer.

2. The display device according to claim 1, wherein the color of the light emitted by the light emitting layer of each of the plurality of pixel regions is substantially the same as the filtered color of the color filter element in the same pixel region.

3. The display device according to claim 1, wherein the plurality of color filter elements comprise photosensitive resin or thermosetting resin.

4. The display device according to claim 1, wherein the color filter layer further comprises a plurality of black matrix structures.

5. The display device according to claim 4, wherein in each of the plurality of the pixel regions, a corresponding color filter element of the plurality of color filter elements is disposed in a light emission region and a corresponding black matrix structure of the plurality of black matrix structures is disposed in a non-emission region.

6. The display device according to claim 4, wherein the plurality of black matrix structures comprise photosensitive resin or thermosetting resin.

7. The display device according to claim 1, wherein a refractive index of the light absorption layer and a refractive index of the optical matching layer satisfy:
0.008<[(n1−n2)/(n1+n2)]̂2<0.8,
wherein n1 is the refractive index of the light absorption layer, and n2 is the refractive index of the optical matching layer.

8. The display device according to claim 7, wherein the refractive index of the light absorption layer is less than the refractive index of the optical matching layer.

9. The display device according to claim 8, wherein the refractive index of the optical matching layer is greater than or equal to 1.8.

10. The display device according to claim 1, wherein the light absorption layer comprises a black resin.

11. The display device according to claim 1, wherein the light absorption layer comprises a multi-layer structure formed by alternately stacking different film-layers.

12. The display device according to claim 1, wherein the optical matching layer comprises a multi-layer structure formed by alternately stacking different film-layers.

13. The display device according to claim 1, wherein the active device layer comprises a thin film transistor.

14. The display device according to claim 1, further comprising:
a pixel define layer, disposed between the light emitting layer and the light absorption layer;
a thin film encapsulation layer, disposed on the second transparent electrode;
a glue, disposed on the thin film encapsulation layer, wherein the thin film encapsulation layer and the glue are disposed between the second transparent electrode and the color filter layer; and
a cover, disposed on the color filter layer, wherein the color filter layer is disposed between the glue and the cover.

15. The display device according to claim 14, wherein the color filter layer further comprises a plurality of black matrix structures.

16. The display device according to claim 15, wherein in each of the plurality of the pixel regions, the color filter element is disposed in a light emission region and the black matrix structure is disposed in a non-emission region.

17. The display device according to claim 1, further comprising:
a pixel define layer, disposed between the light emitting layer and the light absorption layer;
a thin film encapsulation layer, disposed on the second transparent electrode;
a glue, disposed on the thin film encapsulation layer, wherein the color filter layer is disposed between the thin film encapsulation layer and the glue; and
a cover, disposed on the glue.

18. The display device according to claim 17, wherein the color filter layer further comprises a plurality of black matrix structures.

19. The display device according to claim 17, further including a planarization layer disposed on the thin film encapsulation layer and between the thin film encapsulation layer and the color filter layer.

20. The display device according to claim 18, wherein in each of the plurality of the pixel regions, a corresponding color filter element of the plurality of color filter elements is disposed in a light emission region and a corresponding black matrix structure of the plurality of black matrix structures is disposed in a non-emission region.
